(19) United States
(12) Patent Application Publication
(10) Pub. No.: US 2024/0395850 A1
(43) Pub. Date: Nov. 28, 2024

(54) LIGHT-EMITTING DIODE WITH MULTIPLE P-TYPE AND N-TYPE JUNCTIONS AND METHOD FOR MANUFACTURING SAME

(71) Applicant: HIGH POWER OPTO. INC., TAICHUNG (TW)

(72) Inventors: Chih-Sung CHANG, TAICHUNG (TW); Wei-Yu YEN, TAICHUNG (TW); Wan-Jou CHEN, TAICHUNG (TW)

(21) Appl. No.: 18/321,388

(22) Filed: May 22, 2023

(51) Int. Cl. H01L 27/15; H01L 33/00; H01L 33/30; H01L 33/36

(52) U.S. Cl. CPC H01L 27/15; H01L 33/0062; H01L 33/30; H01L 33/36; H01L 2933/0016

(57) ABSTRACT

The invention provides a light-emitting diode including a plurality of P-type and N-type diode structures, an upper electrode, and a fusion junction. Each of the P-type and N-type diode structures includes a first conductive semiconductor, an active region and a second conductive semiconductor stacked vertically, and the plurality of P-type and N-type diode structures are stacked vertically to form a light emitter. The upper electrode is formed on the light emitter. The fusion junction is located between two of the plurality of P-type and N-type diode structures and formed by fusing the first conductive semiconductor of one of the P-type and N-type diode structure and the second conductive semiconductor of the adjacent P-type and N-type diode structure. The fusion junction includes a non-conductive fusion portion and a plurality of conductive fusion portions dispersed in the non-conductive fusion portion excluding a designated area of the non-conductive fusion portion.

### FIELD OF THE INVENTION

The invention relates to a light-emitting diode, and more particularly, to a light-emitting structure of a high-brightness light-emitting diode.

### BACKGROUND OF THE INVENTION

The light-emitting principle of light-emitting diode (LED) is to apply forward bias (current) on the III-V group compound semiconductor material, and use the combination of electrons and holes in the diode to convert electric energy into the form of light. When the energy is released, it can emit light, and the temperature is much lower than that of incandescent bulb. The light-emitting diode has small size, long life, low driving voltage, fast reaction rate, excellent shock resistance, and can meet the light, thin and miniaturized requirements of various equipment. It has long been a very popular product in daily life.

In order to meet the use requirements for high-brightness light emission, such as street lamps, headlights and searchlights of automobiles, etc. the U.S. patent U.S. Pat. No. 7,932,526 B2 provides two P-type and N-type diode structures stacked together, and thus theoretically consumes twice the voltage and increases the power per unit area at the same current.

However, in the epitaxial fabrication of stacked P-type and N-type diode structures, there is an epitaxial problem of lattice mismatch, and the wafer quality of the upper layer is worse. In practical cases, under the same input current, the voltage is 2.1 times that of the light-emitting diode of a single P-type and N-type structure, but only 1.7 times of light-emitting power can be generated.

Therefore, in order to avoid the epitaxy problem of lattice mismatch, it is known from U.S. Pat. No. 8,581,093 B2 to use a transparent junction structure for bonding different P-type and N-type diode structures. Although the light transmittance of the transparent junction structure is above 60%, in fact, the loss of the additionally absorbed light is considerable, which is unfavorable for the use of high-brightness light-emitting diodes.

### SUMMARY OF THE INVENTION

The primary object of the invention is to provide a light-emitting diode having multiple P-type and N-type junctions, which can satisfy the requirements of a high-brightness light-emitting diode.

Another object of the invention is to provide a method for manufacturing a light-emitting diode having multiple P-type and N-type junctions to produce a light-emitting diode that meets high-brightness requirements.

The structure of the light-emitting diode of the invention includes a plurality of P-type and N-type diode structures, an upper electrode, and a fusion junction. Each of the P-type and N-type diode structures includes a first conductive semiconductor, an active region, and a second conductive semiconductor stacked vertically. The plurality of P-type and N-type diode structures are stacked vertically to form a light emitter, and the first conductive semiconductor of one of the plurality of P-type and N-type diode structure is stacked with the second conductive semiconductor of an adjacent P-type and N-type diode structure. The first conductive semiconductor is doped with a first material, and the second conductive semiconductor is doped with a second material. The upper electrode is formed on the light emitter. The fusion junction is located between two of the plurality of P-type and N-type diode structures, and the fusion junction is doped with the first material and the second material. The fusion junction is formed by fusing the first conductive semiconductor of one of the plurality of P-type and N-type diode structure and the second conductive semiconductor of the adjacent P-type and N-type diode structure. The fusion junction comprises a non-conductive fusion portion and a plurality of conductive fusion portions electrically conducting the first conductive semiconductor and the second conductive semiconductor. The plurality of conductive fusion portions is dispersed in the non-conductive fusion portion excluding a part of the non-conductive fusion portion below the upper electrode.

The method for manufacturing a light-emitting diode according to the invention comprises the steps of: preparing the a plurality of P-type and N-type diode structures; stacking the plurality of P-type and N-type diode structures up and down to form the light emitter, whereby the first conductive semiconductor of one of the plurality of P-type and N-type diode structures is stacked on the second conductive semiconductor of an adjacent P-type and N-type diode structure; forming a fusion junction between two of the plurality of P-type and N-type diode structures, wherein the fusion junction is formed with a non-conductive fusion portion and a plurality of conductive fusion portions dispersed in the non-conductive fusion portion excluding a designated area of the non-conductive fusion portion; forming the electrode on the light emitter, and the upper electrode corresponding to the designated area.

Accordingly, the invention provides a fusion junction between the first conductive semiconductor and the second conductive semiconductor adjacent to each other, thereby avoiding additional absorbed light loss without providing another material layer. In addition, the plurality of conductive fusion portions are dispersed in the non-conductive fusion portion excluding a part of the non-conductive fusion portion below the upper electrode, so that the current can be uniformly dispersed and the area where the current pass through can be controlled, thereby improving the luminous uniformity and the light extraction rate, which can meet the using requirements of the light-emitting diodes with high-brightness.

### BRIEF DESCRIPTION OF THE DRAWINGS

FIG. 1 is a sectional view of a light-emitting diode of the invention.

FIGS. 2A˜2E are schematic diagrams of a method for manufacturing a light-emitting diode of the invention.

FIG. 3 is a schematic diagram of the current flow pattern of the invention.

### DETAILED DESCRIPTION OF THE PREFERRED EMBODIMENTS

The detailed description and the technical content of the invention are described in cooperation with the drawings as follows.

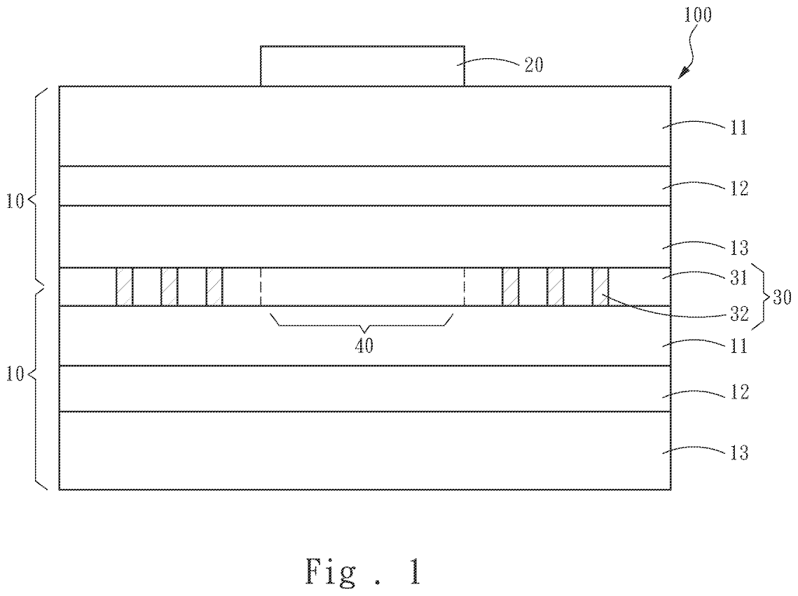

Referring to FIG. 1, the structure of the light-emitting diode includes a plurality of P-type and N-type diode structures 10, an upper electrode 20, and a fusion junction 30. As shown in FIG. 1, the number of the multiple P-type and N-type diode structures 10 is illustrated as two for description.

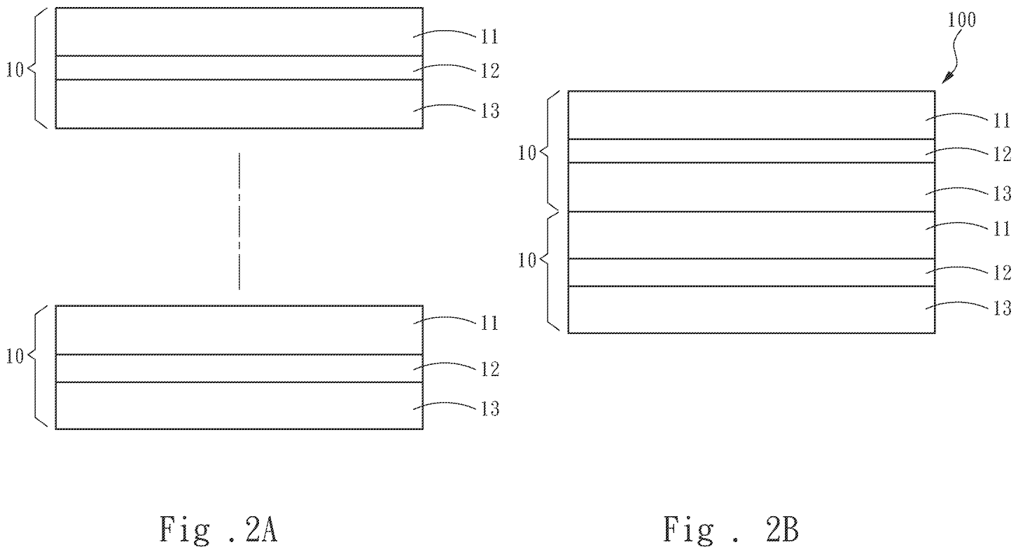

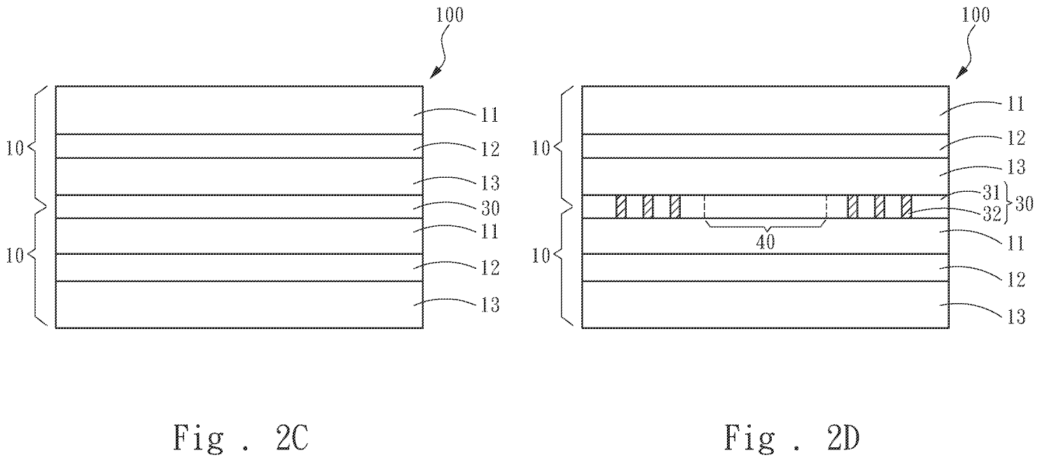

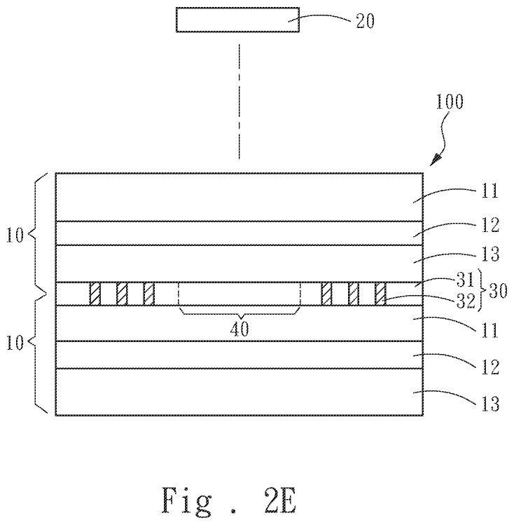

Referring to FIGS. 2A, 2B, 2C, 2D and 2E, a method for manufacturing a light-emitting diode of the invention is illustrated. First, a schematic diagram for preparing the plurality of P-type and N-type diode structures 10 is shown in FIG. 2A. Each of the plurality of P-type and N-type diode structures 10 includes a first conductive semiconductor 11, an active region 12, and a second conductive semiconductor 13. The first conductive semiconductor 11, the active region 12, and the second conductive semiconductor 13 are stacked vertically. The first conductive semiconductor 11 is doped with a first material, and the second conductive semiconductor 13 is doped with a second material. The material system of the plurality of P-type and N-type diode structures 10 is Aluminum gallium indium arsenide phosphide (AlGaInAsP). In one embodiment, the first conductive semiconductor 11 is made of AlGaAs, the active region is made of InGaAs, and the second conductive semiconductor 13 is made of AlInGaP. The first material is selected from the group consisting of Group III arsenide-phosphide, and the second material is selected from the group consisting of Group III arsenide-phosphide.

Next, as shown in FIG. 2B, the plurality of P-type and N-type diode structures 10 are stacked vertically to form a light emitter 100, and the first conductive semiconductor 11 of one of the plurality of P-type and N-type diode structure 10 is stacked with the second conductive semiconductor 13 of the adjacent P-type and N-type diode structure 10.

Next, as shown in FIG. 2C, in one embodiment, the fusion junction 30 is formed between two of the plurality of P-type and N-type diode structures 10. The fusion junction 30 is located between two of the plurality of P-type and N-type diode structures 10, and the fusion junction 30 is doped with the first material and the second material. The fusion junction 30 is formed by fusing the first conductive semiconductor 11 and the second conductive semiconductor 13. In detail, the fusion junction 30 is formed by applying a treatment between two of the plurality of P-type and N-type diode structures 10, and the treatment is any of heating, striking a plasma, and combining heating with striking a plasma.

Further, as shown in FIG. 2D, in order to increase the uniformity of light emission and the light extraction rate, a non-conductive fusion portion 31 and a plurality of conductive fusion portions 32 are formed in the fusion junction 30. The plurality of conductive fusion portions 32 are dispersed in the non-conductive fusion portion 31 and electrically conduct the first conductive semiconductor 11 and the second conductive semiconductor 13, wherein the fusion junction 30 comprises a designated area 40 where the plurality of conductive fusion portions 32 are not dispersed therein.

In one embodiment, the material of the non-conductive fusion portions 31 is undoped aluminum gallium indium arsenide phosphide (AlGaInAsP), which is formed in the fusion junction 30 by the following methods. When the first conductive semiconductor 11 is doped with the first material, an undoped region is reserved in advance; likewise, when the second conductive semiconductor 13 is doped with the second material, an undoped region is reserved in advance; thus, when the first conductive semiconductor 11 and the second conductive semiconductor 13 are fused together to form the fusion junction 30, an undoped region is reserved to form the non-conductive fusion portion 31, while doped areas are formed as the plurality of conductive fusion portions 32.

In another embodiment, the non-conductive fusion portion 31 is formed by filling a non-conductive material selected from any of oxides and nitrides. By filling the non-conductive material, the fusion junction 30 is subjected to a local area oxidation or nitridation process, and the oxidized or nitridated areas are filled with the non-conductive material.

Finally, as shown in FIG. 2E, the upper electrode 20 is formed on the light emitter 100, and the upper electrode 20 corresponds to the designated area 40 of the fusion junction 30, i.e. a part of the non-conductive fusion portion 31 below the upper electrode 20 is not dispersed with the plurality of conductive fusion portions 32.

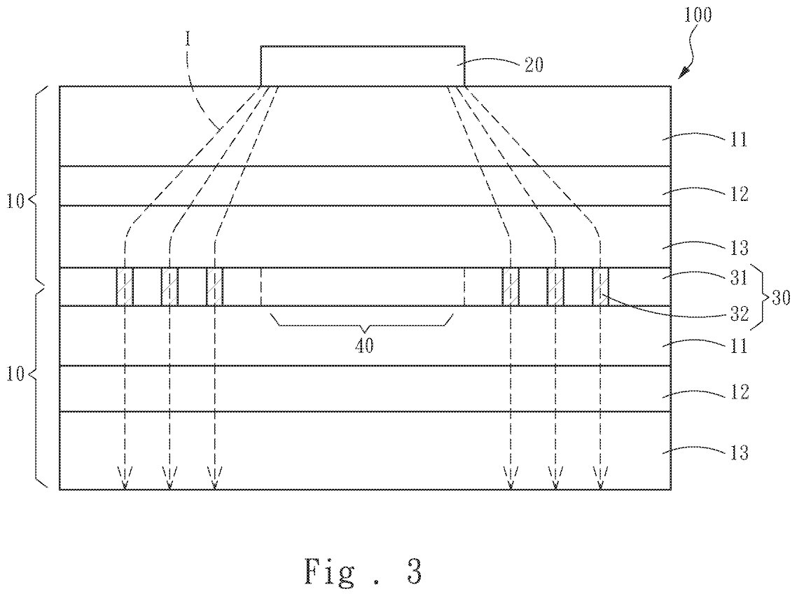

Referring to FIG. 3, since the part of the non-conductive fusion portion 31 below the upper electrode 20 is not dispersed with the plurality of conductive fusion portions 32, when current I enters the light emitter 100 from the upper electrode 20, the current I can only pass through the plurality of conductive fusion portions 32 and parts of the active region 12 which are not located at the corresponding position of the upper electrode 20, thereby generating excitation light that is less shielded by the upper electrode 20 and increasing the extraction rate of excitation light. The plurality of conductive fusion portions 32 guides the current I to disperse, so the luminescence uniformity of the excitation light is increased.

The upper electrode 20 is formed on the light emitter 100. More specifically, the upper electrode 20 is disposed on the outermost surface of the plurality of P-type and N-type diode structures 10. In one embodiment, the upper electrode 20 is arranged on the first conductive semiconductor 11 of the outermost surface of the P-type and N-type diode structures 10, and a side of the light emitter 100 where the upper electrode 20 is arranged is used as a light-emitting surface of the light emitter 100.

Accordingly, the advantages of the invention include at least:
1. The first conductive semiconductor and the second conductive semiconductor adjacent to each other to form the fusion junction, thereby avoiding additional absorbed light loss without providing another material layer.
2. The plurality of conductive fusion portions are dispersed in the non-conductive fusion portion to allow uniform current distribution, thereby improving light emission uniformity.
3. A part of the non-conductive fusion portion below the upper electrode is not dispersed with the plurality of conductive fusion portions to control the passage of current through the region and thereby increase the light extraction rate.

What is claimed is:

1. A light-emitting diode with multiple P-type and N-type junctions, comprising:
a plurality of P-type and N-type diode structures, each of the P-type and N-type diode structures comprising a first conductive semiconductor, an active region, and a second conductive semiconductor stacked vertically, wherein the plurality of P-type and N-type diode structures are stacked vertically to form a light emitter, and wherein the first conductive semiconductor of one of the plurality of P-type and N-type diode structure is stacked with the second conductive semiconductor of an adjacent P-type and N-type diode structure, and wherein the first conductive semiconductor is doped with a first material, and the second conductive semiconductor is doped with a second material;
an upper electrode, formed on the light emitter; and
a fusion junction, located between two of the plurality of P-type and N-type diode structures, and the fusion junction doped with the first material and the second material, wherein the fusion junction is formed by fusing the first conductive semiconductor of one of the plurality of P-type and N-type diode structure and the second conductive semiconductor of the adjacent P-type and N-type diode structure, and wherein the fusion junction comprises a non-conductive fusion portion and a plurality of conductive fusion portions electrically conducting the first conductive semiconductor and the second conductive semiconductor, and wherein the plurality of conductive fusion portions are dispersed in the non-conductive fusion portion excluding a part of the non-conductive fusion portion below the upper electrode.

2. The light-emitting diode with multiple P-type and N-type junctions as claimed in claim 1, wherein a material system of the plurality of P-type and N-type diode structures is aluminum gallium indium arsenide phosphide.

3. The light-emitting diode with multiple P-type and N-type junctions as claimed in claim 2, wherein a material of the non-conductive fusion portion is undoped aluminum gallium indium arsenide phosphide.

4. The light-emitting diode with multiple P-type and N-type junctions as claimed in claim 1, wherein the non-conductive fusion portion is formed by filling a non-conductive material selected from any of oxides and nitrides.

5. The light-emitting diode with multiple P-type and N-type junctions as claimed in claim 1, wherein the fusion junction is formed by applying a treatment between two of the plurality of P-type and N-type diode structures, and wherein the treatment is any of heating, striking a plasma, and combining heating with striking a plasma.

6. A method for manufacturing a light-emitting diode with multiple P-type and N-type junctions, comprising the steps of:
preparing a plurality of P-type and N-type diode structures, each of the P-type and N-type diode structures is formed by stacking a first conductive semiconductor, an active region and a second conductive semiconductor vertically, doping a first material in the first conductive semiconductor, and doping a second material in the second conductive semiconductor;
stacking the plurality of P-type and N-type diode structures vertically to form a light emitter, whereby the first conductive semiconductor of one of the plurality of P-type and N-type diode structures is stacked on the second conductive semiconductor of an adjacent P-type and N-type diode structure;
forming a fusion junction between two of the plurality of P-type and N-type diode structures, wherein the fusion junction is formed with a non-conductive fusion portion and a plurality of conductive fusion portions dispersed in the non-conductive fusion portion excluding a designated area of the non-conductive fusion portion, and wherein the plurality of conductive fusion portions electrically conduct the first conductive semiconductor and the second conductive semiconductor; and
forming an upper electrode on the light emitter, and the upper electrode corresponding to the designated area.

7. The method as claimed in claim 6, wherein a material system of the plurality of P-type and N-type diode structures is aluminum gallium indium arsenide phosphide.

8. The method as claimed in claim 7, wherein a material of the non-conductive fusion portion is undoped aluminum gallium indium arsenide phosphide.

9. The method as claimed in claim 6, wherein the non-conductive fusion portion is formed by filling a non-conductive material selected from any of oxides and nitrides.

10. The method as claimed in claim 6, wherein the fusion junction is formed by applying a treatment between two of the plurality of P-type and N-type diode structures, and wherein the treatment is any of heating, striking a plasma, and combining heating with striking a plasma.
